(19) United States
(12) Patent Application Publication
(10) Pub. No.: US 2023/0178366 A1
(43) Pub. Date: Jun. 8, 2023

(54) SEMICONDUCTOR SUBSTRATE AND MANUFACTURE THEREOF

(71) Applicants: Zing Semiconductor Corporation, Shanghai (CN); Shanghai Institute of Microsystem and Information Technology, Chinese Academy of Sciences, Shanghai (CN)

(72) Inventors: Xing WEI, Shanghai (CN); Rongwang DAI, Shanghai (CN); Ziwen WANG, Shanghai (CN); Hongtao XU, Shanghai (CN); Meng CHEN, Shanghai (CN); Minghao LI, Shanghai (CN)

(73) Assignees: Zing Semiconductor Corporation, Shanghai (CN); Shanghai Institute of Microsystem and Information Technology, Chinese Academy of Sciences, Shanghai (CN)

(21) Appl. No.: 18/073,533

(22) Filed: Dec. 1, 2022

(30) Foreign Application Priority Data
Dec. 3, 2021 (CN) 202111467522.9

(51) Int. Cl. H01L 21/02

(52) U.S. Cl. CPC H01L 21/02255; H01L 21/02271; H01L 21/02323; H01L 21/02164

(57) ABSTRACT

The present application provides a semiconductor substrate and a preparation process thereof. In the present application, the polysilicon layer includes the first polysilicon layer and the second polysilicon layer formed separately to generate the less stress, the more random grain orientation and the smaller grain size, maintain the high grain boundary density, and enhance the charge capture. By the combination of different deposition temperature and the combination of two cooling steps after each isothermal annealing treatment, the rate of contraction between the first polysilicon layer and the second polysilicon layer and the initial semiconductor substrate is decreased, and the thermal mismatch of semiconductor substrate is reduced. The stretch between the polysilicon layer and the initial semiconductor substrate can be reduced to prevent the warpage of the semiconductor substrate. Thereby, the stress generated during the growth process of the polysilicon layer can be further reduced.

### BACKGROUND OF THE INVENTION

### 1. Field of the Invention

The present invention relates to manufacture of semiconductor, and more particularly to a semiconductor substrate and manufacture thereof.

### 2. Description of the Related Art

Polysilicon layer has strong charge trapping capability because of its internal texture properties and high grain boundary density, such that it can be applied for basic substrate such as monocrystal silicon substrate in the radio frequency field and used as trap-rich layer to capture residual free charges at high frequency. Internal grain boundary and stress distribution are critical for quality of polysilicon layer of the substrate. Due to preferred orientation and grain aggregation of polysilicon during epitaxial growth process, the grain boundaries at different thickness levels exist with different density distributions. Charge capture capability directly depends on the total amount of the grain boundaries of polysilicon. Because the lattice mismatch and the different thermal expansion coefficients between the polysilicon layer and the monocrystal silicon substrate, large stress exists between the polysilicon layer and the monocrystal silicon substrate, causing the bow and warpage of the polysilicon layer. The bow and warpage of the polysilicon layer become more significant with the increase of thickness of the polysilicon layer. Further, the size of polysilicon grain and the existence of defect impurity inside the polysilicon layer also affect the stress and warpage of the semiconductor substrate. High stress and warpage have adverse effects on subsequent processes, which restrict the applications of the semiconductor substrate with polysilicon layer.

### SUMMARY

The present application provides a semiconductor substrate and a process thereof. The process for forming a semiconductor substrate comprising the following steps: S1: providing an initial semiconductor substrate, wherein the initial semiconductor substrate comprises a first surface oxide layer thereon; S2: forming a first polysilicon layer on the first surface oxide layer at a first temperature to form a semiconductor substrate I; S3: increasing the first temperature to a second temperature, and conducting an isothermal annealing treatment to the semiconductor substrate I at the second temperature; S4: conducting a first reduction of temperature from the second temperature to the first temperature, then conducting a first natural cooling to the semiconductor substrate I while the first temperature is achieved, wherein the first reduction of temperature has a reduction rate smaller than that of the first natural cooling; S5: conducting an oxidation treatment to the first polysilicon layer to decrease the thickness of the first polysilicon layer and form a second surface oxide layer; S6: forming a second polysilicon layer on the second surface oxide layer at a third temperature to form a semiconductor substrate II; S7: increasing the third temperature to a fourth temperature, and conducting an isothermal annealing treatment to the semiconductor substrate II at the fourth temperature; and, S8: conducting a second reduction of temperature from the fourth temperature to the third temperature, then conducting a second natural cooling to the semiconductor substrate II while the third temperature is achieved, wherein the second reduction of temperature has a reduction rate smaller than that of the second natural cooling.

### BRIEF DESCRIPTION OF THE DRAWINGS

FIG. 1 is a flowchart illustrating method steps for forming the semiconductor substrate in accordance with one embodiment of the present application.

FIG. 2a illustrates the structure of the initial semiconductor substrate in accordance with one embodiment of the present application.

FIG. 2b illustrates the structure of the initial semiconductor substrate after the formation of the first polysilicon layer in accordance with one embodiment of the present application.

FIG. 2c illustrates the structure of the semiconductor substrate after the formation of the second surface oxide layer in accordance with one embodiment of the present application.

FIG. 2d illustrates the structure of the semiconductor substrate after the formation of the second polysilicon layer in accordance with one embodiment of the present application.

FIG. 3 is a diagram illustrating the relationship between temperature and time during the preparation process of the semiconductor substrate in accordance with one embodiment of the present application.

### DETAILED DESCRIPTION OF THE EMBODIMENTS

The purpose of the present application is to provide a semiconductor substrate and its manufacturing process to reduce stress generated from formation of a polysilicon layer, thereby to reduce the bow and the warpage of the semiconductor substrate.

The present application provides a process for manufacturing a semiconductor substrate comprising the following steps:

S1: providing an initial semiconductor substrate, wherein the initial semiconductor substrate comprises a first surface oxide layer thereon;
S2: forming a first polysilicon layer on the first surface oxide layer at a first temperature to form a semiconductor substrate I;
S3: increasing the first temperature to a second temperature, and conducting an isothermal annealing treatment to the semiconductor substrate I at the second temperature;
S4: conducting a first reduction of temperature from the second temperature to the first temperature, then conducting a first natural cooling to the semiconductor substrate I at the first temperature, wherein the first reduction of temperature has a reduction rate smaller than that of the first natural cooling;
S5: conducting an oxidation treatment to the first polysilicon layer to decrease the thickness of the first polysilicon layer and form a second surface oxide layer;
S6: forming a second polysilicon layer on the second surface oxide layer at a third temperature to form a semiconductor substrate II;
S7: increasing the third temperature to a fourth temperature, and conducting an isothermal annealing treatment to the semiconductor substrate II at the fourth temperature; and
S8: conducting a second reduction of temperature from the fourth temperature to the third temperature, then conducting a second natural cooling to the semiconductor substrate II at the third temperature, wherein the second reduction of temperature has a reduction rate smaller than that of the second natural cooling.

In the present application, the initial semiconductor substrate can be a basic substrate such as a monocrystal silicon substrate with the first oxide layer formed thereon. The semiconductor substrate I can be an intermediate semiconductor substrate during the manufacture process, which comprises the basic substrate, the first oxide layer and the first polysilicon layer. The semiconductor substrate II comprises the basic substrate, the first oxide layer, the first polysilicon layer, the second surface oxide layer and the second polysilicon layer. The semiconductor substrate II can be the final semiconductor substrate of the manufacture process of the present application.

In one embodiment, the Step S2 comprises:

feeding the initial semiconductor substrate to a CVD reaction chamber, and conducting a first heating to achieve the first temperature;
at the first temperature, growing the first polysilicon layer on the first surface oxide layer by atmospheric pressure chemical vapor deposition; and
wherein the first heating is under an atmosphere of hydrogen, and the atmosphere is converted to a mixed gas containing hydrogen and trichlorosilane while the first temperature is achieved.

In one embodiment, in the first heating, the hydrogen has a gas flow of 40 slm-80 slm, the mixed gas has the hydrogen gas flow of 40 slm-80 slm and the trichlorosilane gas flow of 3 slm-2 slm, and the first temperature is 900° C.-1000° C.

In one embodiment, the Step S3 comprises: conducting a second heating and simultaneously converting the atmosphere to hydrogen gas; and while the second temperature is achieved, conducting the isothermal annealing treatment to the semiconductor substrate I, wherein the second temperature is 1050° C.-1200° C.

In one embodiment, the Step S4 comprises:

conducting the first reduction of temperature in the CVD reaction chamber and maintaining the atmosphere of hydrogen;
while the first temperature is achieved, transferring the semiconductor substrate I out from the CVD reaction chamber; and
conducting the first natural cooling to the semiconductor substrate I under ambient environment, wherein the first natural cooling has a cooling rate of 0.5° C./s-3° C./s.

In one embodiment, the Step S5 comprises:

laying the semiconductor substrate I under ambient environment to naturally reduce the thickness of the first polysilicon layer, and forming the second surface oxide layer on the first polysilicon layer, wherein the second surface oxide layer has a thickness of 1 nm-1.5 nm; or
reducing the thickness of the first polysilicon layer by an oxidation step under an atmosphere of dry oxygen and/or wet oxygen, and forming the second surface oxide layer on the first polysilicon layer, wherein the first polysilicon layer has a reduced thickness of 1 nm-1.5 nm.

In one embodiment, the Step S6 comprises:

transferring the semiconductor substrate I into the CVD reaction chamber, and conducting a third heating to achieve the third temperature;
at the third temperature, growing the second polysilicon layer on the surface oxide layer by atmospheric pressure chemical vapor deposition to form the semiconductor substrate II; and
wherein the third heating is under hydrogen atmosphere, and the atmosphere is converted to a mixed gas containing hydrogen and trichlorosilane while the third temperature is achieved.

In one embodiment, in the third heating, the hydrogen has a gas flow of 40 slm-80 slm, the mixed gas has the hydrogen gas flow of 40 slm-80 slm and the trichlorosilane gas flow of 3 slm-12 slm, and the third temperature is 900° C.-1000° C.

In one embodiment, the Step S7 comprises: conducting a fourth heating and simultaneously converting the atmosphere to hydrogen gas; and while the fourth temperature is achieved, conducting the isothermal annealing treatment to the semiconductor substrate II, wherein the fourth temperature is 1050° C.-1200° C.

In one embodiment, the Step S8 comprises:

conducting the second reduction of temperature in the CVD reaction chamber and maintaining the atmosphere of hydrogen;
while the third temperature is achieved, transferring the semiconductor substrate II out from the CVD reaction chamber; and
conducting the second natural cooling to the semiconductor substrate II under ambient environment, wherein the second natural cooling has a cooling rate of 0.5° C./s-3° C./s.

In another aspect, the present application provides a semiconductor substrate characterized by that the semiconductor substrate is prepared by the above process.

Compared with conventional technologies, the present application provides the following effects and advantages.

In the present application, the polysilicon layer contains the first polysilicon layer and the second polysilicon layer, and the first polysilicon layer and the second polysilicon layer are separately formed, causing less stress between the initial semiconductor substrate and the polysilicon layer, more random grain orientation and finer grain size of the polysilicon layer. High grain boundary density of the polysilicon layer is still maintained.

Compared with the conventional polysilicon layer formed by one step, under the same thickness, the polysilicon layer of the present application formed by two separate epitaxy steps has less lattice mismatch and is able to reduce the entire stress. Moreover, the rate of contraction between the first polysilicon layer and the second polysilicon layer and the initial semiconductor substrate can be decreased by the two cooling steps (the reduction of temperature and the natural cooling in the Steps S4 and S8) after each isothermal annealing treatment, such that the thermal mismatch of semiconductor substrate is reduced. The stretch between the polysilicon layer and the initial semiconductor substrate can be reduced to prevent the warpage of the semiconductor substrate. Thereby, the stress generated during the growth process of the polysilicon layer can be further reduced.

### EXAMPLES

### Example 1

For a thorough understanding of the present invention, the detailed steps will be set forth in detail in the following description in order to explain the technical solution of the present invention. The preferred embodiments of the present invention is described in detail as follows, however, in addition to the detailed description, the present invention also may have other embodiments.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

Example embodiments will now be described more fully with reference to the accompanying drawings. Noted that accompanying drawing is simplified and applies non-accurately ratio for the purpose of clear and convenient illustration of the example of the present invention.

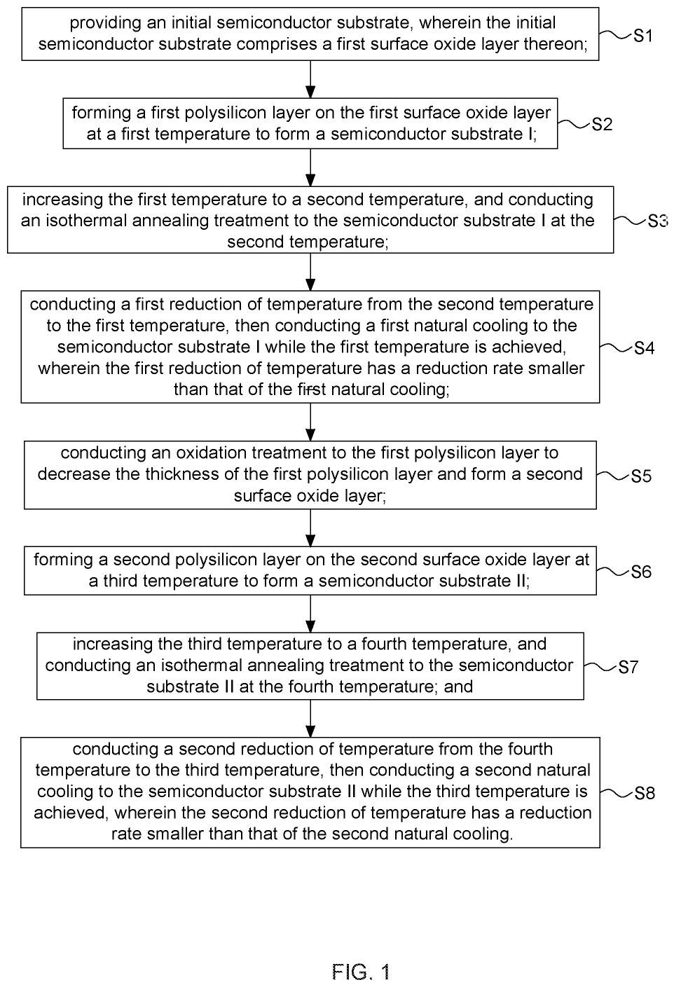

FIG. 1 is a flowchart illustrating method steps for forming the semiconductor substrate in accordance with one embodiment of the present application. As shown in FIG. 1, this example provides a process for forming a semiconductor substrate comprising the following steps:

S1: providing an initial semiconductor substrate, wherein the initial semiconductor substrate comprises a first surface oxide layer thereon;
S2: forming a polysilicon layer on the first surface oxide layer at a first temperature to form a semiconductor substrate I;
S3: increasing the first temperature to a second temperature, and conducting an isothermal annealing treatment to the semiconductor substrate I at the second temperature;
S4: conducting a first reduction of temperature from the second temperature to the first temperature, then conducting a first natural cooling to the semiconductor substrate I at the first temperature, wherein the first reduction of temperature has a reduction rate smaller than that of the first natural cooling;
S5: conducting an oxidation treatment to the first polysilicon layer to decrease the thickness of the first polysilicon layer and form a second surface oxide layer;
S6: forming a second polysilicon layer on the second surface oxide layer at a third temperature to form a semiconductor substrate II;
S7: increasing the third temperature to a fourth temperature, and conducting an isothermal annealing treatment to the semiconductor substrate II at the fourth temperature; and
S8: conducting a second reduction of temperature from the fourth temperature to the third temperature, then conducting a second natural cooling to the semiconductor substrate II at the third temperature, wherein the second reduction of temperature has a reduction rate smaller than that of the second natural cooling.

Referring FIG. 1-3, the process is further described in detail.

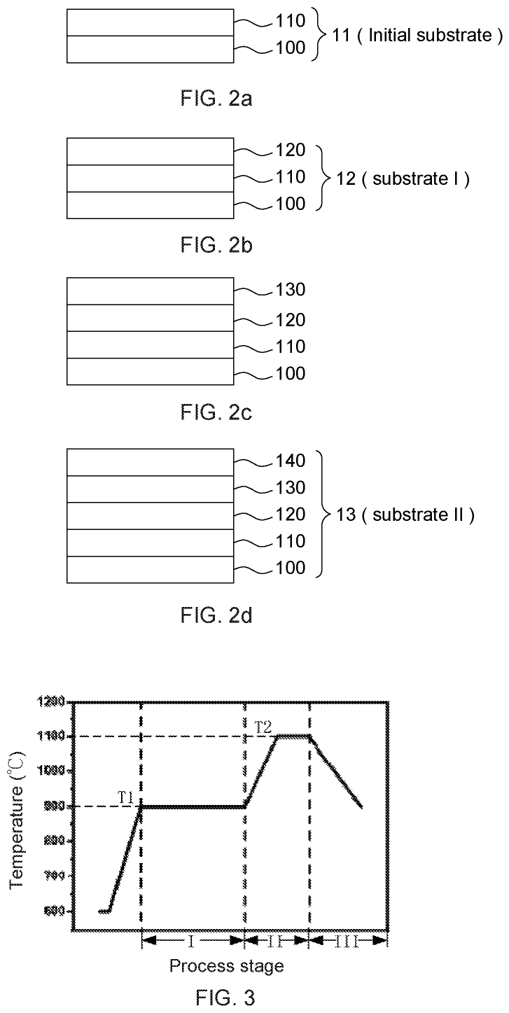

FIG. 2a illustrates the structure of the initial semiconductor substrate of this example. FIG. 3 illustrates the relationship between temperature and time during the process for forming the semiconductor substrate of this example. As shown in FIG. 2a and FIG. 3, the Step S1 is firstly conducted to provide an initial semiconductor substrate 11. The initial semiconductor substrate 11 comprises a basic semiconductor substrate 100 and a first surface oxide layer 110 formed thereon. The basic semiconductor substrate 100 can be, for example, monocrystal silicon substrate. The first surface oxide layer 110 can be an oxide film formed via natural oxidation of the monocrystal silicon substrate under ambient environment, i.e. oxygen-containing environment. The first surface oxide layer 110 has a thickness of, for example, 1 nm-1.5 nm.

FIG. 2b illustrates the structure of the semiconductor substrate I. As shown in FIG. 2b and FIG. 3, the Step S2 is conducted to form a first polysilicon layer 120 on the first surface oxide layer 110 at a first temperature T1. The detail of this step is described as follows.

The initial semiconductor substrate 11 is transferred into a CVD reaction chamber. The device temperature is 500° C.-800° C. The device atmosphere is hydrogen. The hydrogen has a gas flow of 40 slm-80 slm.

The first heating is conducted to achieve the first temperature T1. The atmosphere of hydrogen and the gas flow of 40 slm-80 slm is maintained during this heating. The first temperature T1 is 900° C.-1000° C.

While the first temperature T1 is achieved, it enters the process stage I (the first isothermal stage). At the first temperature T1, the atmosphere is converted to a mixed gas containing hydrogen and trichlorosilane, and the first polysilicon layer 120 grows on the first surface oxide layer 110 by atmospheric pressure chemical vapor deposition. The mixed gas has the hydrogen gas flow of 40 slm-80 slm and the trichlorosilane gas flow of 3 slm-12 slm. Accordingly, the semiconductor substrate I (i.e. the semiconductor substrate 12) is obtained.

Continuously referring FIG. 3, the Step S3 is conducted to increase the first temperature T1 to the second temperature T2, and conducting an isothermal annealing treatment to the semiconductor substrate 12 at the second temperature T2. Specifically, it enters the process stage II that the semiconductor substrate 12 is subjected to the isothermal annealing treatment. The process stage II comprises the second heating treatment and a second isothermal treatment.

In this step, the second heating is conducted and the atmosphere is simultaneously converted to hydrogen gas. While the second temperature T2 is achieved, the isothermal annealing treatment is conducted under the atmosphere of hydrogen. The second temperature T2 is 1050° C.-1200° C. The isothermal annealing treatment to the semiconductor substrate 12 can release the stress between the first polysilicon layer 120 and the initial semiconductor substrate 11, thereby the bow and warpage of the semiconductor substrate 12 can be reduced.

Continuously referring FIG. 3, the Step S4 is conducted to enter the process stage III. The first reduction of temperature is conducted from the second temperature T2 to the first temperature T1. While the first temperature is achieved, the first natural cooling is conducted to the semiconductor substrate 12. In particular, the first reduction of temperature has a reduction rate smaller than that of the first natural cooling. In this step, the first natural cooling from the first temperature T1 is able to decrease the cooling rate of the semiconductor substrate 12. Accordingly, the rate of contraction between the first polysilicon layer 120 and the initial semiconductor substrate 11 is decreased, the stretch between the first polysilicon layer 120 and the initial semiconductor substrate 11 is reduced, the thermal mismatch of the semiconductor substrate 12 is reduced, and the stress generated during the growth of the first polysilicon layer 120 can be eliminated.

In this step, the first reduction of temperature is conducted in the CVD reaction chamber and the atmosphere of hydrogen is maintained. This temperature reduction rate can be the routine cooling rate applied in the CVD and is relative slow. While the first temperature T1 is achieved, the semiconductor substrate 12 is transferred out from the CVD reaction chamber and subjected to the first natural cooling under ambient environment. The first natural cooling has a cooling rate of 0.5° C./s-3° C./s.

FIG. 2c illustrates the structure after the formation of the second surface oxide layer. As shown in FIG. 2c, the Step S5 is conducted to oxidize the first polysilicon layer 120 to decrease the thickness of the first polysilicon layer 120 and form the second surface oxide layer 130.

In this step, the semiconductor substrate 12 is transferred to an oxidation furnace to oxidize the surface of the first polysilicon layer 120 to form the second surface oxide layer 130 under an atmosphere of dry oxygen and/or wet oxygen. Namely, the atmosphere for oxidation can be dry oxygen, wet oxygen or a mixture of dry oxygen and wet oxygen. The oxidation temperature can be 800° C.-1000° C. In a preferred embodiment, the oxidation temperature is 900° C.-950° C. The oxidation treatment is applied to reduce the thickness of the first polysilicon layer 120. The reduced first polysilicon layer 120 has a thickness of 1 nm-1.5 nm.

Alternatively, in this step, the semiconductor substrate 12 can be laid in a natural environment. Under the ambient environment, the first polysilicon layer 120 reacts with oxygen in the environment to form the second surface oxide layer 130 on its surface. The second surface oxide layer 130 is a natural oxidation layer with a thickness of 1 nm-1.5 nm. A further natural oxidation layer has a thickness of 1.5 nm.

FIG. 2d illustrates the structure of the semiconductor substrate II after the formation of the second polysilicon layer. As shown in FIG. 2d, the Step S6 is conducted to form the second polysilicon layer 140 on the second surface oxide layer 130 at the third temperature to form the semiconductor substrate II. The detail is described as follows.

Firstly, the semiconductor substrate 12 with the second surface oxide layer 130 is transferred to the CVD reaction chamber. The device temperature is 500° C.-800° C. The device atmosphere is hydrogen and the hydrogen has a gas flow of 40 slm-80 slm.

The third heating is conducted under the atmosphere of hydrogen to achieve the third temperature. The hydrogen has a gas flow of 40 slm-80 slm. The third temperature is 900° C.-1000° C.

While the third temperature is achieved, the third isothermal treatment is conducted. At the third temperature, the atmosphere is converted to a mixed gas containing hydrogen and trichlorosilane, and the second polysilicon layer 140 grows on the second surface oxide layer 130 by atmospheric pressure chemical vapor deposition. In this step, the mixed gas has the hydrogen gas flow of 40 slm-80 slm and the trichlorosilane gas flow of 3 slm-12 slm. Accordingly, the semiconductor substrate II (i.e. the semiconductor substrate 13) is obtained.

Then, the Step S7 is conducted to increase the third temperature to the fourth temperature, and conduct an isothermal annealing treatment to the semiconductor substrate 13 at the fourth temperature.

The detail of this step is described as follows.

While the third heating starts, the atmosphere is simultaneously converted to hydrogen gas. The fourth heating is conducted to achieve the fourth temperature, and the fourth isothermal treatment is then conducted. The atmosphere of hydrogen is maintained to the fourth isothermal treatment. The fourth temperature is 1050° C.-1200° C., which is applied to the isothermal annealing treatment of the semiconductor substrate 13. Thereby, the stress between the second polysilicon layer 140 and the semiconductor substrate 12 is released to eliminate the bow and warpage of the semiconductor substrate 13. In this example, the fourth temperature can be identical to the second temperature.

The Step S8 is conducted. The second reduction of temperature is applied to cool the fourth temperature to the third temperature. While the third temperature is achieved, the semiconductor substrate 13 is subjected to the second natural cooling. The second reduction of temperature has a reduction rate smaller than that of the second natural cooling. In this step, the second natural cooling from the third temperature is able to decrease the cooling rate of the semiconductor substrate 13. Accordingly, the rate of contraction between the second polysilicon layer 140 and the semiconductor substrate 12 is decreased, the thermal mismatch of the semiconductor substrate 13 is reduced, the stretch between the second polysilicon layer 140 and the semiconductor substrate 12 is reduced, the warpage of initial semiconductor substrate 13 can be further reduced, and the stress generated during the growth of the second polysilicon layer 140 can be eliminated. The detail of this step is described as follows.

In the CVD reaction chamber, the second reduction of temperature is conducted under the atmosphere of hydrogen. This temperature reduction rate can be the routine cooling rate applied in the CVD and this cooling is relative fast. while the third temperature is achieved, the initial semiconductor substrate 100 is transferred out from the CVD reaction chamber and subjected to the second natural cooling under ambient environment, which is cooled relative slowly. The second natural cooling has a cooling rate of 0.5° C./s-3° C./s.

Due to the random distribution of nucleation point during the initial growth of the polysilicon layer, the random crystal orientation is generated at the interface between the polysilicon layer and the natural oxidation layer. Thereby, many twin boundaries are formed to increase the boundary density of the polysilicon layer. With the growth of the polysilicon layer, i.e. the increase of thickness of the polysilicon layer, the polysilicon selectively grows along with certain crystal orientation, also known as preferred orientation, to form columnar grain, causing the smooth distribution of the thickness of the grain boundary density. In this example, the bi-layered polysilicon layer including the first polysilicon layer 120 and the second polysilicon layer 140 is formed by twice growth processes. Each polysilicon layer always grows on the surface of the polysilicon close to the initial semiconductor substrate 100, and is in a state of high grain boundary density of the initial growth stage. Compared with the conventional technologies, under the same thickness of polysilicon layer, this example is able to increase the total number of grain boundary in the polysilicon layer, such that the probability and quantity of charge capture can be enhanced to a certain extent, and the phenomenon of excessive warpage caused by the overall stress of the polysilicon layer can be also alleviated.

This example also provides a semiconductor substrate prepared by the above process.

According to the above, the present application provides a semiconductor substrate and a process thereof. The process for forming a semiconductor substrate comprises the following steps: S1: providing an initial semiconductor substrate, wherein the initial semiconductor substrate comprises a first surface oxide layer thereon; S2: forming a first polysilicon layer on the first surface oxide layer at a first temperature to form a semiconductor substrate I; S3: increasing the first temperature to a second temperature, and conducting an isothermal annealing treatment to the semiconductor substrate I at the second temperature; S4: conducting a first reduction of temperature from the second temperature to the first temperature, then conducting a first natural cooling to the semiconductor substrate I while the first temperature is achieved, wherein the first reduction of temperature has a reduction rate smaller than that of the first natural cooling; S5: conducting an oxidation treatment to the first polysilicon layer to decrease the thickness of the first polysilicon layer and form a second surface oxide layer; S6: forming a second polysilicon layer on the second surface oxide layer at a third temperature to form a semiconductor substrate II; S7: increasing the third temperature to a fourth temperature, and conducting an isothermal annealing treatment to the semiconductor substrate II at the fourth temperature; and, S8: conducting a second reduction of temperature from the fourth temperature to the third temperature, then conducting a second natural cooling to the semiconductor substrate II while the third temperature is achieved, wherein the second reduction of temperature has a reduction rate smaller than that of the second natural cooling.

In the present application, the polysilicon layer includes the first polysilicon layer and the second polysilicon layer formed separately to generate the less stress between the initial semiconductor substrate and the polysilicon layer, the more random grain orientation and the smaller grain size in the polysilicon layer, and maintain the high grain boundary density. Compared with the conventional polysilicon layer formed by one step, under the same thickness, the polysilicon layer of the present application formed by two separate epitaxy growth steps has less lattice mismatch and is able to reduce the entire stress. Moreover, the rate of contraction between the first polysilicon layer and the second polysilicon layer and the initial semiconductor substrate can be decreased by the two cooling steps (i.e. the reduction of temperature and the natural cooling in the Steps S4 and S8) after each isothermal annealing treatment, such that the thermal mismatch of semiconductor substrate is reduced. The stretch between the polysilicon layer and the initial semiconductor substrate can be reduced to prevent the warpage of the semiconductor substrate. Thereby, the stress generated during the growth process of the polysilicon layer can be further reduced.

Although the terms first, second, third, etc. may be used herein to describe various elements, components, and/or steps, these elements, components, and/or steps should not be limited by these terms. These terms may be only used to distinguish one element, component, and/or steps, from another element, component, and/or steps. Terms such as “first,” “second,” and other numerical terms when used herein do not imply a sequence or order unless clearly indicated by the context. Thus, a first element, component, or steps discussed below could be termed a second element, component, or steps without departing from the teachings of the example embodiments.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims and its equivalent systems and methods.

What is claimed is:

1. A process for forming a semiconductor substrate comprising the following steps:
S1: providing an initial semiconductor substrate, wherein the initial semiconductor substrate comprises a first surface oxide layer thereon;
S2: forming a first polysilicon layer on the first surface oxide layer at a first temperature to form a semiconductor substrate I;
S3: increasing the first temperature to a second temperature, and conducting an isothermal annealing treatment to the semiconductor substrate I at the second temperature;
S4: conducting a first reduction of temperature from the second temperature to the first temperature, then conducting a first natural cooling to the semiconductor substrate I while the first temperature is achieved, wherein the first reduction of temperature has a reduction rate smaller than that of the first natural cooling;
S5: conducting an oxidation treatment to the first polysilicon layer to decrease the thickness of the first polysilicon layer and form a second surface oxide layer;
S6: forming a second polysilicon layer on the second surface oxide layer at a third temperature to form a semiconductor substrate II;
S7: increasing the third temperature to a fourth temperature, and conducting an isothermal annealing treatment to the semiconductor substrate II at the fourth temperature; and
S8: conducting a second reduction of temperature from the fourth temperature to the third temperature, then conducting a second natural cooling to the semiconductor substrate II while the third temperature is achieved, wherein the second reduction of temperature has a reduction rate smaller than that of the second natural cooling.

2. The process of claim 1, wherein the step S2 comprises:
feeding the initial semiconductor substrate to a CVD reaction chamber, and conducting a first heating to achieve the first temperature;
at the first temperature, growing the first polysilicon layer on the first surface oxide layer by atmospheric pressure chemical vapor deposition; and
wherein the first heating is under an atmosphere of hydrogen, and the atmosphere is converted to a mixed gas containing hydrogen and trichlorosilane while the first temperature is achieved.

3. The process of claim 2, wherein the hydrogen has a gas flow of 40 slm-80 slm, the mixed gas has the hydrogen gas flow of 40 slm-80 slm and the trichlorosilane gas flow of 3 slm-12 slm, and the first temperature is 900° C.-1000° C.

4. The process of claim 2, wherein the step S3 comprises:
conducting a second heating and simultaneously converting the atmosphere to hydrogen gas;
while the second temperature is achieved, conducting the isothermal annealing treatment to the semiconductor substrate I, wherein the second temperature is 1050° C.-1200° C.

5. The process of claim 1, wherein the step S4 comprises:
conducting the first reduction of temperature in the CVD reaction chamber and maintaining the atmosphere of hydrogen;
while the first temperature is achieved, transferring the semiconductor substrate I out from the CVD reaction chamber; and
conducting the first natural cooling to the semiconductor substrate I under ambient environment, wherein the first natural cooling has a cooling rate of 0.5° C./s-3° C./s.

6. The process of claim 1, wherein the step S5 comprises:
reducing the thickness of the first polysilicon layer by a natural placement, and forming the second surface oxide layer on the first polysilicon layer, wherein the second surface oxide layer has a thickness of 1 nm-1.5 nm; or
reducing the thickness of the first polysilicon layer by an oxidation step under an atmosphere of dry oxygen and/or wet oxygen, and forming the second surface oxide layer on the first polysilicon layer, wherein the first polysilicon layer has a reduced thickness of 1 nm-1.5 nm.

7. The process of claim 1, the step S6 comprises:
transferring the semiconductor substrate I into the CVD reaction chamber, and conducting a third heating to achieve the third temperature;
at the third temperature, growing the second polysilicon layer on the surface oxide layer by atmospheric pressure chemical vapor deposition to form the semiconductor substrate II; and
wherein the third heating is under hydrogen atmosphere, and the atmosphere is converted to a mixed gas containing hydrogen and trichlorosilane while the third temperature is achieved.

8. The process of claim 7, wherein the hydrogen has a gas flow of 40 slm-80 slm, the mixed gas has the hydrogen gas flow of 40 slm-80 slm and the trichlorosilane gas flow of 3 slm-12 slm, and the third temperature is 900° C.-1000° C.

9. The process of claim 7, wherein the step S7 comprises:
conducting a fourth heating and simultaneously converting the atmosphere to hydrogen gas;
while the fourth temperature is achieved, conducting the isothermal annealing treatment to the semiconductor substrate II, wherein the fourth temperature is 1050° C.-1200° C.

10. The process of claim 1, wherein the step S8 comprises:
conducting the second reduction of temperature in the CVD reaction chamber and maintaining the atmosphere of hydrogen;
while the third temperature is achieved, transferring the semiconductor substrate II out from the CVD reaction chamber; and
conducting the second natural cooling to the semiconductor substrate II under ambient environment, wherein the second natural cooling has a cooling rate of 0.5° C./s-3° C./s.

11. A semiconductor substrate characterized by: the semiconductor substrate is prepared by claim 1.
